(19) United States
(12) Patent Application Publication
(10) Pub. No.: US 2026/0063477 A1
(43) Pub. Date: Mar. 5, 2026

(54) ELECTRONIC DEVICE AND METHOD FOR PREDICTING DUST ACCUMULATION IN COOLING VENT THEREOF

(71) Applicant: CHROMA ATE INC., Taoyuan City (TW)

(72) Inventors: Mao-Nan Guo, Taoyuan City (TW); Chun-Tai Cheng, Taoyuan City (TW); Wei-Chin Tseng, Taoyuan City (TW); Szu-Chieh Su, Taoyuan City (TW); Kun-Hsien Chen, Taoyuan City (TW)

(73) Assignee: CHROMA ATE INC., Taoyuan City (TW)

(21) Appl. No.: 19/210,190

(22) Filed: May 16, 2025

(30) Foreign Application Priority Data
Aug. 28, 2024 (TW) 113132437

(51) Int. Cl. G01K 7/42; G01K 3/04; G08B 21/18; H05K 5/02; H05K 7/20

(52) U.S. Cl. CPC G01K 7/427; G01K 3/04; G08B 21/185; H05K 5/0214; H05K 7/20009; G01K 2213/00

(57) ABSTRACT

An electronic device and a method for predicting dust accumulation in a cooling vent thereof are provided. The electronic device includes a housing, a power supply board, an environmental temperature sensing module, a work area temperature sensing module, a storage, and a processor. The environmental temperature sensing module is configured to measure an environmental temperature inside the housing. The work area temperature sensing module is configured to measure a working temperature of a work area. The processor is configured to respectively calculate an average environmental temperature and an average working temperature based on a plurality of environmental temperatures and a plurality of working temperatures in an analysis period, and calculate an estimated value of dust accumulation in the cooling vent. The processor is configured to send a warning signal when the estimated value of dust accumulation is greater or equal to a dust accumulation warning value.

### CROSS-REFERENCE TO RELATED APPLICATION

This non-provisional application claims priority under 35 U.S.C. § 119(a) to Patent Application No. 113132437 filed in Taiwan, R.O.C. on Aug. 28, 2024, the entire contents of which are hereby incorporated by reference.

### BACKGROUND

### Technical Field

The present invention provides an electronic device and a method for predicting dust accumulation in a cooling vent thereof, and in particular, an electronic device for preventing thermal overload of the electronic device based on an estimated value of dust accumulation in a cooling vent and a method for predicting dust accumulation in a cooling vent thereof.

### Related Art

Currently, during operation of an electronic device product (such as a power supply), a circuit board thereof generates heat energy due to output of a power supply or operation of an electronic element. If the heat energy is not discharged out of a housing of electronic device product, thermal overload may occur in the housing due to serious heat energy accumulation, which causes an error or a failure of to the electronic device product. Therefore, the housing of the electronic device product is provided with a cooling vent to discharge the heat energy inside the housing. However, as air flows, dust or dirt in the air accumulates at a cooling vent after a long period of time, which reduces a heat discharge effect of the cooling vent. Therefore, thermal overload may still occur in the electronic device product.

### SUMMARY

In some embodiments, an electronic device is provided, including a housing, a power supply board, an environmental temperature sensing module, a work area temperature sensing module, a storage, and a processor. The housing includes a cooling vent. The power supply board is located in the housing, is configured to output a load current, and has a work area. The environmental temperature sensing module is located in the housing, and is configured to measure an environmental temperature inside the housing. The work area temperature sensing module is arranged in work area, and is configured to measure a working temperature of the work area. The storage is configured to store the environmental temperature and the working temperature when the load current is in a stable state. The processor is configured to: respectively calculate an average environmental temperature and an average working temperature based on a plurality of environmental temperatures and a plurality of working temperatures stored in the storage in an analysis period, and calculate an estimated value of dust accumulation in the cooling vent based on the average environmental temperature and the average working temperature. The processor is configured to send a warning signal when the estimated value of dust accumulation is greater or equal to a dust accumulation warning value.

In some embodiments, a method for predicting dust accumulation in a cooling vent of an electronic device is provided, including: measuring an environmental temperature and a working temperature; storing the environmental temperature and working temperature when a load current is in a stable state; extracting, based on a data extraction cycle, a plurality of environmental temperatures and a plurality of working temperatures that are stored, and respectively calculating an average environmental temperature and an average working temperature; calculating an estimated value of dust accumulation in the cooling vent based on the average environmental temperature and the average working temperature; and sending a warning signal when the estimated value of dust accumulation is greater or equal to a dust accumulation warning value.

To sum up, based on some embodiments, according to the electronic device and the method for predicting dust accumulation in a cooling vent thereof, a degree of dust accumulation in the cooling vent is estimated, and a user is prompted to clean the cooling vent of the electronic device in advance, so as to ensure a good heat dissipation capability of the cooling vent.

Specific features and advantages of the present invention are described in detail in the following implementations, and the content is sufficient for any person skilled in the related art to understand the technical content of the present invention and implement the present invention accordingly. Based on the content, the patent application scope, and the drawings disclosed in this specification, any person skilled in the related art can easily understand the related objective and advantage of the present invention.

### BRIEF DESCRIPTION OF THE DRAWINGS

FIG. 1 is a schematic three-dimensional view of an electronic device according to some embodiments of the present invention.

FIG. 2 is a block diagram of the electronic device according to some embodiments of the present invention.

FIG. 3 is a flowchart of a method for predicting dust accumulation in a cooling vent of an electronic device according to some embodiments of the present invention.

FIG. 4 is a flowchart of a method for predicting dust accumulation in a cooling vent of an electronic device according to some other embodiments of the present invention.

### DETAILED DESCRIPTION

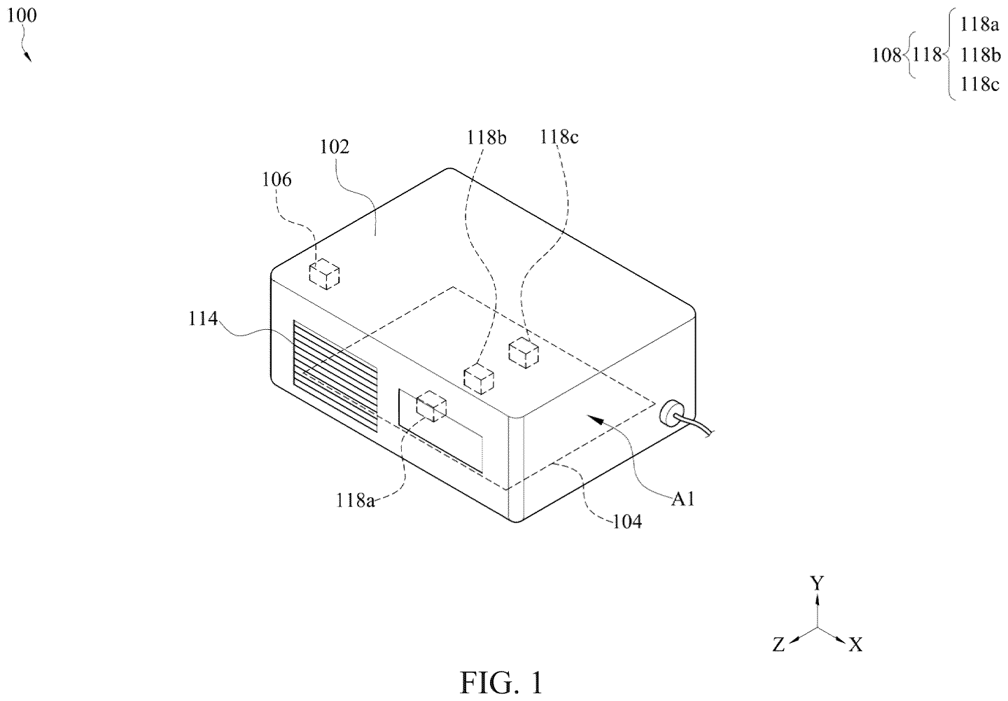

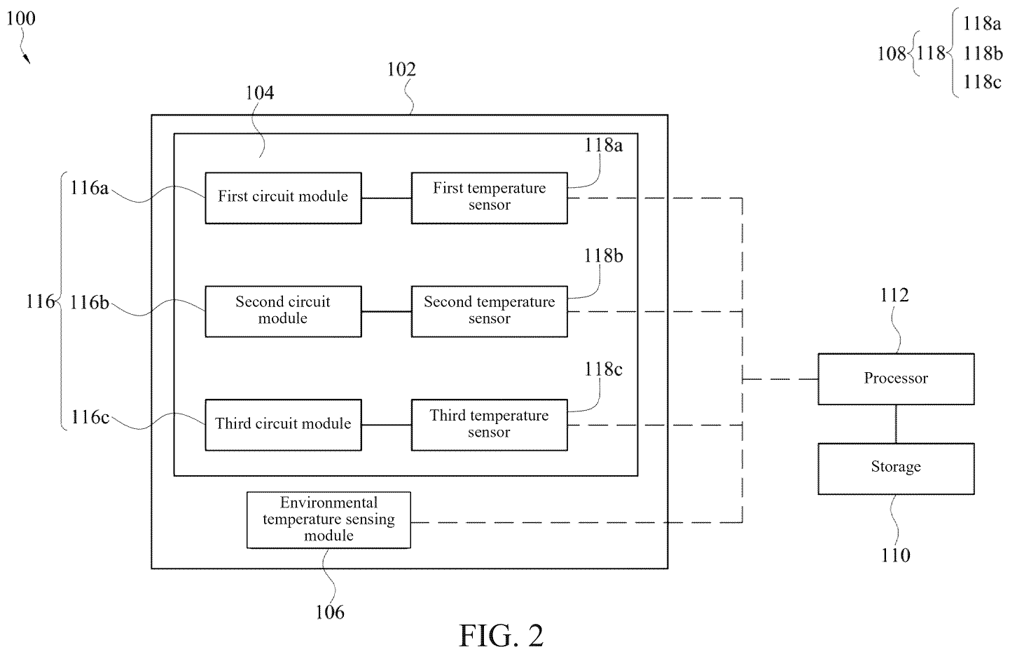

Refer to FIG. 1 and FIG. 2. FIG. 1 is a schematic three-dimensional view of an electronic device according to some embodiments of the present invention. FIG. 2 is a block diagram of the electronic device according to some embodiments of the present invention. In some embodiments, as shown in FIG. 1 and FIG. 2, an electronic device 100 includes a housing 102, a power supply board 104, an environmental temperature sensing module 106, a work area temperature sensing module 108, a storage 110, and a processor 112. The housing 102 includes a cooling vent 114. The power supply board 104 is located in the housing 102, is configured to output a load current, and has a work area A1. The environmental temperature sensing module 106 is located in the housing 102, and is configured to measure an environmental temperature inside the housing 102. The work area temperature sensing module 108 is arranged in work area A1, and is configured to measure a working temperature of the work area A1. The storage 110 is configured to store the environmental temperature and the working temperature when the load current is in a stable state. The processor 112 is configured to: extract, based on a data extraction cycle, a plurality of environmental temperatures and a plurality of working temperatures stored in the storage 110, respectively calculate an average environmental temperature and an average working temperature, and calculate an estimated value of dust accumulation in the cooling vent 114 based on the average environmental temperature and the average working temperature. The processor 112 is configured to send a warning signal when the estimated value of dust accumulation is greater or equal to a dust accumulation warning value.

The cooling vent 114 of the housing 102 may refer to at least one opening provided on the housing 102 to dissipate heat of the power supply board 104 (for example, the cooling vent 114 is a combination of at least one air inlet and at least one air outlet). In some embodiments, the cooling vent 114 may be provided with a dust blocking structure (e.g., a filter mesh) to prevent dust from entering the housing 102. In this case, the estimated value of dust accumulation may refer to a degree to which the heat dissipation of the cooling vent 114 is hindered. When the estimated value of dust accumulation is less than the dust accumulation warning value, it means that the heat dissipation of the cooling vent 114 is still not hindered by dust. If the estimated value of dust accumulation is greater than or equal to the dust accumulation warning value, it means that the heat dissipation of the cooling vent 114 is hindered by dust, and the power supply board 104 may not perform heat dissipation normally, resulting in thermal overload.

The power supply board 104 is a circuit board configured to supply power. When the power supply board 104 is connected to a load, the power supply board may output a load current to the load.

The environmental temperature sensing module 106 and the work area temperature sensing module 108 may be, for example, thermocouples, resistance temperature detectors, semiconductor temperature sensors, or infrared temperature sensors. The environmental temperature sensing module 106 may be arranged on any inner wall surface of the housing 102, to measure a temperature of an internal space of the housing 102 (the temperature is referred to as an environmental temperature). The work area temperature sensing module 108 may be arranged on the power supply board 104 (for example, the work area temperature sensing module 108 is integrated into a circuit of the work area A1 or arranged in the work area A1), to measure the temperature of the work area A1 on the power supply board 104 (the temperature is referred to as a working temperature). In some embodiments, the environmental temperature sensing module 106 and the work area temperature sensing module 108 may perform a measurement task based on a first driving signal. In some examples, the environmental temperature sensing module 106 and the work area temperature sensing module 108 are communicatively connected to the processor 112, and is configured to receive a second driving signal or send the working temperature and the environmental temperature. The environmental temperature sensing module 106 and the work area temperature sensing module 108 may be further electrically connected to the power supply board 104, and is configured to receive instructions and send the working temperature and the environmental temperature through the power supply board 104.

The storage 110 may be, for example, one or a combination of any two or more of a non-volatile memory, a flash memory, a solid-state drive (SSD), a read-only memory (ROM), a hard disk drive (HDD), and a network hard disk. In some examples, the storage 110 may perform a storage task based on the second driving signal. In some examples, the storage 110 may be arranged outside the housing 102, and the storage 110 is respectively communicatively connected to the environmental temperature sensing module 106, the work area temperature sensing module 108, and the processor 112, and is configured to receive the second driving signal, the working temperature, and the environmental temperature, or to send the working temperature and the environmental temperature stored in the storage 110. In some examples, the storage 110 may be arranged on the power supply board 104, and is configured to receive the second driving signal, the working temperature, and the environmental temperature or to send the working temperature and the environmental temperature stored in the storage 110 through the power supply board 104. In some examples, the memory 110 further correspondingly stores a data storage time when storing each working temperature and environmental temperature.

The processor 112 is configured to calculate the estimated value of dust accumulation in the cooling vent 114 and send a warning signal based on a result of comparison between the estimated value of dust accumulation and the dust accumulation warning value. The processor 112 may be, for example, a central processing unit (CPU), a graphics processing unit (GPU), a digital signal processor (DSP), or a field-programmable gate array (FPGA). In some examples, the processor 112 is configured to send the first driving signal when the load current is in the stable state. The stable state may mean that the load current is substantially equal to a maximum load current and the state lasts for a preset loading time. An error range between the load current and the maximum load current may be ±2%, and the preset loading time may be one minute. For example, when the load current reaches ±2% of the maximum load current, the processor 112 may start counting to determine whether the state lasts for one minute. If the load current reaches the maximum load current but the state last for less than one minute, the processor 112 waits for the load current to reach the maximum load current again and then starts counting. It should be noted that, when the measured load current is the maximum load current, the load current is more stable than that existing when the power supply board 104 is initially mounted. In some examples, the processor 112 is configured to send the second driving signal when the load current is in the stable state for a measurement evaluation time. The measurement evaluation time may be twenty minutes. If the load current is in the stable state for a duration exceeding the measurement evaluation time, the load current reaches a stable load state, and the working temperature and the environmental temperature reach a stable state, so that the estimated value of dust accumulation can be close to an actual dust accumulation situation (which improves an estimation accuracy). In some examples, the processor 112 may be arranged on the power supply board 104, and is configured to receive the load current, the working temperature, and the environmental temperature through the power supply board 104, or to send the first driving signal, the second driving signal, and the warning signal through the power supply board 104. In some examples, the processor 112 may be arranged outside the housing 102, is communicatively connected to the power supply board 104, the storage 110, the environmental temperature sensing module 106, and the work area temperature sensing module 108, and is configured to remotely receive the load current, the working temperature, and the environmental temperature, or to remotely send the first driving signal, the second driving signal, and the warning signal.

The processor 112 may extract, based on the data extraction cycle, the data stored in the storage 110. The data extraction cycle may be a “day” or a “week”. It should be noted that a length of the data extraction cycle may be adjusted based on a degree of dirt of an environment in which the electronic device 100 is arranged. If the environment is a low-altitude dirty site, the data extraction cycle may be set to “one week” or “more than one week”. If the environment is a high-altitude dirty site, the data extraction cycle may be set to “three days”. After extracting a plurality of working temperatures and a plurality of environmental temperatures in a current data extraction cycle, the processor 112 may calculate an average environmental temperature and an average working temperature in the current data extraction cycle, and calculate an estimated value of dust accumulation corresponding to the current data extraction cycle accordingly. In other words, the processor 112 may regularly calculate the estimated value of dust accumulation and determine whether the cooling vent 114 needs to be cleaned, so as to ensure normal operation of the electronic device 100 by reducing the dust accumulation of the cooling vent 114. In some examples, the processor 112 may extract the temperature data of the current data extraction cycle based on the data storage time. The processor 112 may further clear the data stored in the storage 110 after extracting the data of the current data extraction cycle, to extract latest data of each cycle.

In some embodiments, the processor 112 obtains the estimated value of dust accumulation based on a multivariate linear regression model. As shown in the following formula 1, the multivariate linear regression model includes two independent variables, and the two independent variables are respectively the average environmental temperature and the average working temperature. The processor 112 executes the multivariate linear regression model, and substitutes an average environmental temperature and an average working temperature of a current cycle into the multivariate linear regression model to calculate an estimated value of dust accumulation.

$$Estimated value of dust accumulation = {a}_{1} T + {a}_{2} {T}_{env} + {a}_{3} . \qquad ( Formula 1 )$$

a₁, a₂, and a₃ are regression coefficients.
T is a working temperature.
Tₑₙᵥ is an environmental temperature.

In some embodiments, the work area A1 has a plurality of circuit modules 116, and the work area temperature sensing module 108 has a plurality of temperature sensors 118. Each temperature sensor 118 is configured to measure a module temperature of each circuit module 116. An average of the module temperatures is the working temperature of the work area A1. Taking FIG. 2 as an example, the circuit module 116 includes a first circuit module 116a, a second circuit module 116b, and a third circuit module 116c. The temperature sensor 118 includes a first temperature sensor 118a, a second temperature sensor 118b, and a third temperature sensor 118c. The first temperature sensor 118a is configured to measure a module temperature of the first circuit module 116a (referred to as a first module temperature herein). The second temperature sensor 118b is configured to measure a module temperature of the second circuit module 116b (referred to as a second module temperature herein). The third temperature sensor 118c is configured to measure a module temperature of the third circuit module 116c (referred to as a third module temperature herein). The processor 112 may use an average of the first module temperature, the second module temperature, and the third module temperature as the working temperature of the work area A1.

In some embodiments, the plurality of circuit modules 116 each have an independent function. For example, the electronic device 100 in FIG. 2 is a power supply. The first circuit module 116a, the second circuit module 116b, and the third circuit module 116c are direct current-direct current converters and are coupled in sequence, and each converts a voltage outputted from a preceding level to a voltage required for a succeeding level. Finally, an output of the third circuit module 116c serves as a power supply for a device under test (DUT).

In some embodiments, the multivariate linear regression model includes a plurality of regression coefficients, the regression coefficients are calculated through a linear least squares method based on a regression coefficient set of each of the plurality of multivariate linear regression sub-models, and each multivariate linear regression sub-model corresponds to each circuit module 116. In other words, after the data of each circuit module 116 (average environmental temperatures and average working temperatures at different levels of dust accumulation) is collected, the regression coefficient in the formula 1 is determined through regression analysis based on the formula 1, so as to obtain the multivariate linear regression sub-model corresponding to each circuit module 116. For example, regression analysis is performed on data of the first circuit module 116a to establish a first multivariate linear regression sub-model, regression analysis is performed on data of the second circuit module 116b to establish a second multivariate linear regression sub-model, and regression analysis is performed data of the third circuit module 116c to establish a third multivariate linear regression sub-model. Regression coefficients of the first multivariate linear regression sub-model constitute a first regression coefficient set. Regression coefficients of the second multivariate linear regression sub-model constitute a second regression coefficient set. Regression coefficients of the third multivariate linear regression sub-model constitute a third regression coefficient set. An optimal regression coefficient set (that is, the regression coefficient of the multivariate linear regression model) is obtained through fitting by using a linear least squares method based on the regression coefficient sets.

The above “average environmental temperatures and average working temperatures at different levels of dust accumulation” may be air intake flows at different amounts of dust accumulation (levels of dust accumulation) at the cooling vent 114 simulated after one or more shielding plates are arranged at the cooling vent 114. Specifically, when more shielding plates are arranged, an air intake flow at the cooling vent 114 decreases, which simulates an air intake flow at the cooling vent 114 with dust accumulation. In other words, a larger quantity of shielding plates indicates a higher level of dust accumulation. For example, one shielding plate may be defined as a first level of dust accumulation (slight dust accumulation), two shielding plates may be defined as a second level of dust accumulation (moderate dust accumulation), and three shielding plates may be defined as a third level of dust accumulation (serious level of dust accumulation). A working temperature of each circuit module (116a, 116b, 116c) changes with a level of dust accumulation. Specifically, a working temperature measured at the first level of dust accumulation is lower than a working temperature measured at the second level of dust accumulation, and the working temperature measured at the second level of dust accumulation is lower than a working temperature measured at the third level of dust accumulation. In this way, the working temperature of each circuit module (116a, 116b, 116c) under a different shielding plate quantity can be measured, so that the optimal regression coefficient set can be obtained through fitting by using the linear least squares method.

In some exemplary embodiments, the dust accumulation warning value is negatively correlated with the environmental temperature. In other words, a larger average environmental temperature indicates a smaller dust accumulation warning value.

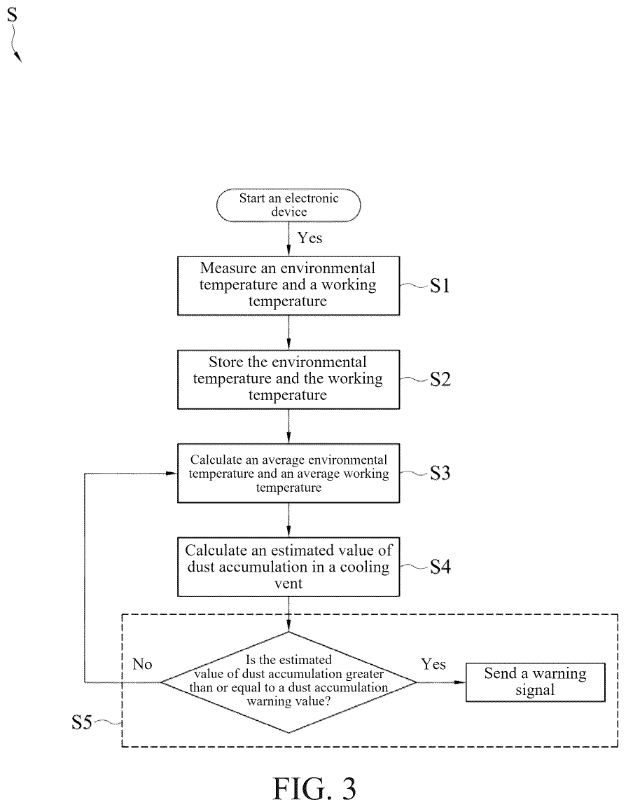

As shown in FIG. 3, in some embodiments, a method S for predicting dust accumulation in a cooling vent of an electronic device 100 includes the following steps: measuring an environmental temperature and a working temperature (step S1); storing the environmental temperature and working temperature when a load current is in a stable state (step S2); extracting, based on a data extraction cycle, a plurality of environmental temperatures and a plurality of working temperatures that are stored, and respectively calculating an average environmental temperature and an average working temperature (step S3); calculating an estimated value of dust accumulation in the cooling vent based on the average environmental temperature and the average working temperature (step S4); and sending a warning signal when the estimated value of dust accumulation is greater or equal to a dust accumulation warning value (step S5).

In some embodiments, the processor 112 of the electronic device 100 is configured to perform the method S for predicting dust accumulation of a cooling vent of an electronic device. Specifically, in step S1, the processor 112 drives the environmental temperature sensing module 106 and the work area temperature sensing module 108 to measure the environmental temperature and the working temperature. In step S2, the processor 112 stores the environmental temperature and the working temperature based on the condition that the load current is in the stable state. In step S3, the processor 112 calculates the average environmental temperature and the average working temperature based on the plurality of environmental temperatures and the plurality of working temperatures. In step S4, the processor 112 calculates the estimated value of dust accumulation based on the average environmental temperature and the average working temperature. In step S5, the processor 112 sends the warning signal when the estimated value of dust accumulation is greater than or equal to the dust accumulation warning value.

In some embodiments, step S4 further includes: obtaining the estimated value of dust accumulation based on a multivariate linear regression model, where the multivariate linear regression model includes two independent variables, and the two independent variables are respectively the average environmental temperature and the average working temperature.

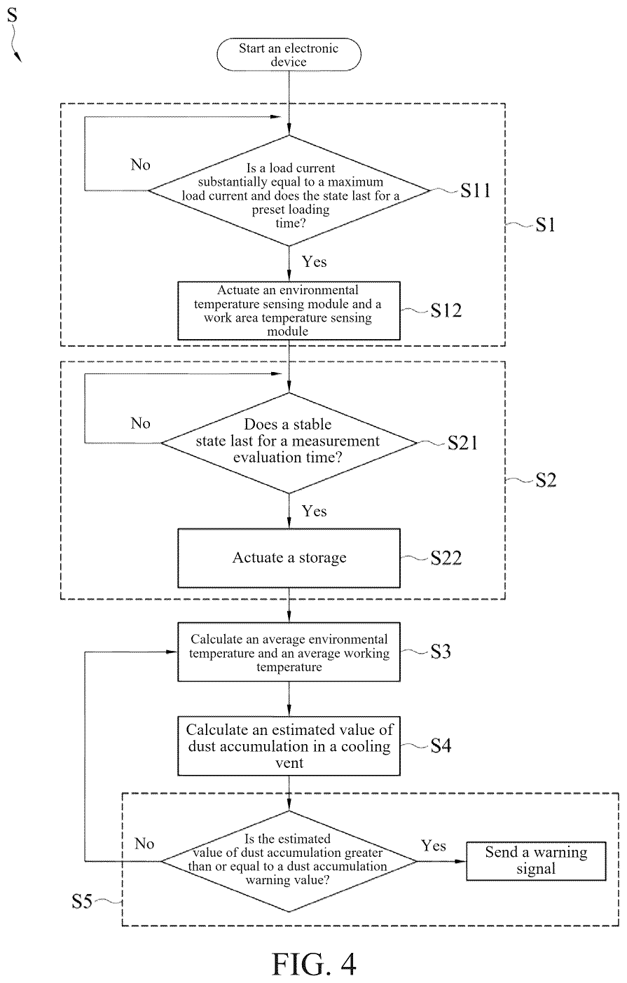

In some embodiments, as shown in FIG. 4, step S1 further includes: determining whether the load current is substantially equal to a maximum load current and determining whether the state lasts for a preset loading time (step S11); and actuating the environmental temperature sensing module 106 and the work area temperature sensing module 108 to measure the environmental temperature and the working temperature (step S12). Step S11 may be used as a precondition for determining whether to measure the environmental temperature and the working temperature. For example, when the processor 112 determines that the load current is substantially equal to the maximum load current (an error may be ±2%), the processor starts counting to determine whether the state lasts for the preset loading time. If so, the processor 112 actuates the environmental temperature sensing module 106 and the work area temperature sensing module 108 (step S12). If not, the processor waits for the load current to reach the maximum load current again and then starts counting.

In some embodiments, as shown in FIG. 4, step S2 further includes: determining whether the load current is in the stable state and determining whether the stable state lasts for a measurement evaluation time (step S21); and actuating the storage 110 to store the environmental temperature and the working temperature (step S22). Step S21 may be used as a precondition for determining whether to store the environmental temperature and the working temperature. For example, the processor 112 may start counting when the load current reaches a stable state, and determine whether the state lasts for the measurement evaluation time. If so, the processor 112 drives the storage 110 to store the data of the environmental temperature and the working temperature (step S22). If not, the processor 112 performs further counting until the measurement evaluation time is reached.

To sum up, based on some embodiments, according to the electronic device 100 and the method S for predicting dust accumulation in a cooling vent thereof, a degree of dust accumulation in the cooling vent 114 is estimated, and a user is prompted to clean the cooling vent 114 of the electronic device 100 in advance, so as to ensure a good heat dissipation capability of the cooling vent 114.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. An electronic device, comprising:
a housing, comprising a cooling vent;
a power supply board, located in the housing, configured to output a load current, and having a work area;
an environmental temperature sensing module, located in the housing and configured to measure an environmental temperature inside the housing;
a work area temperature sensing module, arranged in the work area and configured to measure a working temperature of the work area;
a storage, configured to store the environmental temperature and the working temperature when the load current is in a stable state; and
a processor, configured to: extract, based on a data extraction cycle, a plurality of environmental temperatures and a plurality of working temperatures stored in the storage, respectively calculate an average environmental temperature and an average working temperature, and calculate an estimated value of dust accumulation in the cooling vent based on the average environmental temperature and the average working temperature, wherein
the processor is configured to send a warning signal when the estimated value of dust accumulation is greater or equal to a dust accumulation warning value.

2. The electronic device according to claim 1, wherein the processor is configured to obtain the estimated value of dust accumulation based on a multivariate linear regression model, the multivariate linear regression model comprises two independent variables, and the two independent variables are respectively the average environmental temperature and the average working temperature.

3. The electronic device according to claim 2, wherein the work area has a plurality of circuit modules, the work area temperature sensing module has a plurality of temperature sensors, each temperature sensor is configured to measure a module temperature of each circuit module, and an average of the module temperatures is the working temperature of the work area.

4. The electronic device according to claim 3, wherein the multivariate linear regression model comprises a plurality of regression coefficients, the regression coefficients are calculated through a linear least squares method based on a regression coefficient set of each of the plurality of multivariate linear regression sub-models, and each multivariate linear regression sub-model corresponds to each circuit module.

5. The electronic device according to claim 1, wherein the dust accumulation warning value is negatively correlated with the environmental temperature.

6. A method for predicting dust accumulation in a cooling vent of an electronic device, comprising:
measuring an environmental temperature and a working temperature;
storing the environmental temperature and working temperature when a load current is in a stable state;
extracting, based on a data extraction cycle, a plurality of environmental temperatures and a plurality of working temperatures that are stored, and respectively calculating an average environmental temperature and an average working temperature;
calculating an estimated value of dust accumulation in the cooling vent based on the average environmental temperature and the average working temperature; and
sending a warning signal when the estimated value of dust accumulation is greater or equal to a dust accumulation warning value.

7. The method for predicting dust accumulation in a cooling vent of an electronic device according to claim 6, wherein the step of calculating the estimated value of dust accumulation in the cooling vent based on the average environmental temperature and the average working temperature further comprises:
obtaining the estimated value of dust accumulation based on a multivariate linear regression model, wherein the multivariate linear regression model comprises two independent variables, and the two independent variables are respectively the average environmental temperature and the average working temperature.

8. The method for predicting dust accumulation in a cooling vent of an electronic device according to claim 7, wherein the multivariate linear regression model comprises a plurality of regression coefficients, and the regression coefficients are calculated through a linear least squares method based on a regression coefficient set of each of the plurality of multivariate linear regression sub-models.

9. The method for predicting dust accumulation in a cooling vent of an electronic device according to claim 6, wherein the dust accumulation warning value is negatively correlated with the environmental temperature.

10. The method for predicting dust accumulation in a cooling vent of an electronic device according to claim 6, wherein the step of measuring the environmental temperature and the working temperature further comprises: determining whether the load current is substantially equal to a maximum load current and determining whether the state lasts for a preset loading time; and the step of storing the environmental temperature and the working temperature when the load current is in the stable state further comprises: determining whether the load current is in the stable state and determining whether the stable state lasts for a measurement evaluation time.
